(19) United States
(12) Patent Application Publication
(10) Pub. No.: US 2026/0025914 A1
(43) Pub. Date: Jan. 22, 2026

(54) CIRCUIT BOARD AND METHOD OF FABRICATING THE SAME

(71) Applicants: HongQiSheng Precision Electronics (QinHuangdao) Co., Ltd., Hebei Province (CN); Avary Holding (Shenzhen) Co., Ltd., Shenzhen (CN); Garuda Technology Co., Ltd., New Taipei City (TW)

(72) Inventors: Zhi-Yong HUANG, Hebei Province (CN); Hong-Yu XU, Hebei Province (CN); Yang LU, Hebei Province (CN); Jia-Bao HAN, Hebei Province (CN)

(21) Appl. No.: 18/775,534

(22) Filed: Jul. 17, 2024

(51) Int. Cl. H05K 1/02; H05K 1/03; H05K 3/00; H05K 3/42

(52) U.S. Cl. CPC H05K 1/028; H05K 1/0393; H05K 3/0044; H05K 3/429; H05K 2201/09036; H05K 2203/0502; H05K 2203/1105

(57) ABSTRACT

A circuit board and a method of fabricating the same are provided. The circuit board has a flexible insulation film and a circuit substrate with a bending part. The circuit substrate is a rigid board and includes a plurality of grooves which are distributed in the bending part. Each of the grooves extends to two opposite ends of the circuit substrate in a direction of long axis, and an opening of one of the grooves is exposed to the surface of the circuit substrate. The flexible insulation layer is disposed on the surface of the circuit substrate and covers the opening of the groove, while the groove is not filled with the flexible insulation layer.

### BACKGROUND

### Technical field

The present disclosure relates to a circuit board and the method for fabrication of the same. More particular, the present disclosure relates to a rigid circuit board and the method for fabrication of the same.

### Description of Related Art

Due to the extension of application of circuit boards, the requirements for the bending strength of circuit boards are gradually increasing, in order to meet the needs of various applications. However, since the mechanical properties (e.g., elastic modulus) of rigid circuit boards are limited, the bendable angle of existing rigid circuit boards is between 0° and 20° approximately. Once the bending angle of a circuit board is larger than this bendable angle, the circuit board is obviously damaged or broken. Thus, the rigid circuit board is difficult to tolerate the high bending stress, and the bendable angle of the circuit board is unable to increase.

### SUMMARY

Accordingly, the disclosure is to provide a circuit board and a method for fabrication of the same, and thereby increasing the bending strength of the rigid circuit board.

At least one embodiment of the disclosure provides the method for fabrication the aforementioned circuit board.

At least one embodiment of the disclosure provides a circuit board including a circuit substrate having a bending part. The circuit substrate includes a plurality of grooves and a flexible insulation film. The grooves are distributed in the bending part. Each of the grooves extends to two opposite ends of the circuit substrate in a long axis direction, and a first opening of one of the grooves is exposed on a first surface of the circuit substrate. The circuit substrate is a rigid board. The flexible insulation film is disposed on the first surface of the circuit substrate. The flexible insulation film covers the first openings of the grooves, and the grooves are not filled with the flexible insulation film.

At least in one embodiment of the disclosure, the circuit substrate further includes an insulation layer and two circuit layers. The insulation has a first layer and a second layer. The first layer of the insulation layer is located between the flexible insulation film and the second layer of the insulation layer, and the grooves are distributed in the first layer of the insulation layer. The circuit layers are disposed on the insulation layer, and the insulation layer is located between the circuit layers. One of the circuit layers is located at the first layer of the insulation layer, and the other one of the circuit layers is located at the second layer of the insulation layer.

At least in one embodiment of the disclosure, the circuit board further includes a protective layer disposed on a second surface of the circuit substrate The first surface and the second surface are located at two opposite sides of the circuit substrate separately. One of the circuit layers is located between the insulation layer and the protective layer, and the protective layer covers the one of the circuit layers.

At least in one embodiment of the disclosure, a second opening of another one of the grooves is exposed on the second surface of the circuit substrate, and the protective layer covers the second opening of the another one of the grooves.

At least in one embodiment of the disclosure, the circuit substrate further includes the insulation layer and two circuit layers. The insulation has a first layer and a second layer. The first layer of the insulation layer is located between the flexible insulation film and the second layer of the insulation layer, and the grooves are distributed in the second layer of the insulation layer. The circuit layers are disposed on the insulation layer, and the insulation layer is located between the circuit layers. One of the circuit layers is located at the first layer of the insulation layer, and the other one of the circuit layers is located at the second layer of the insulation layer.

At least in one embodiment of the disclosure, a Young's modulus of the insulation layer is between 50 GPa and 80 GPa.

At least in one embodiment of the disclosure, the circuit board further includes a plurality of conductive vias extending from one of the circuit layers to the other one of the circuit layers and electrically connecting the circuit layers.

At least in one embodiment of the disclosure, the insulation layer of the circuit substrate is an Ajinomoto build-up film.

At least in one embodiment of the disclosure, when the circuit board is under a bending state, the bending part of the circuit substrate is bent around the long axis direction that is as a bending axis, and a cross section of at least one of the grooves is deformed.

At least in one embodiment of the disclosure, when the circuit board is under a flatten state, the cross section of the at least one of the grooves is rectangular.

At least in one embodiment of the disclosure, when the circuit board is under the bending state, the cross section of the at least one of the groove is a bending trapezoid.

At least one embodiment of the disclosure provides a method for fabricating a circuit board. The method includes providing a circuit substrate. A part of the circuit substrate is removed to form a plurality of first grooves on a first surface of the circuit substrate, and each of the first grooves extends to two opposite ends of the circuit substrate in a long axis direction. A pyrolysis material is disposed inside the first grooves, and the pyrolysis temperature of the pyrolysis material is between 150° C. and 200° C. A flexible insulation film is disposed on the first surface of the circuit substrate after the pyrolysis material is disposed, and the flexible insulation film covers the first grooves and the pyrolysis material. The circuit substrate is heated up to the pyrolysis temperature of the pyrolysis material after the flexible insulation film is disposed on the circuit substrate, so as to remove the pyrolysis material.

At least in one embodiment of the disclosure, providing the circuit substrate includes providing an initial circuit substrate which includes an insulation layer and a metal layer disposed on one side of the insulation layer. The metal layer is patterned to form a circuit layer. An insulation substrate is disposed on the circuit layer. The insulation substrate covers the insulation layer and the circuit layer, and the circuit layer is located between the insulation layer and the insulation substrate. A part of the insulation substrate is removed to form a plurality of second grooves on a second surface of the insulation substrate, and each of the second grooves extends to two opposite ends of the insulation substrate in the long axis direction. The pyrolysis material is disposed inside the second grooves. At least one composite substrate is respectively disposed on the second surface of the insulation substrate and a flat of the insulation layer after the pyrolysis material is disposed inside the second grooves. The second surface of the insulation substrate and the flat of the insulation layer back on to the circuit layer, while one of the composite substrates covers the second grooves and the pyrolysis material inside the second grooves.

At least in one embodiment of the disclosure, the method further includes removing another part of the circuit substrate to form a plurality of third grooves on a third surface of the circuit substrate, and the third surface and the first surface are separately located at two opposite sides of the circuit substrate. Each of the third grooves extends to two opposite ends of the circuit substrate in the along axis direction. The pyrolysis material is disposed inside the third grooves. A protective layer is disposed on the third surface of the circuit substrate after the pyrolysis material is disposed inside the third grooves. The protective layer covers the third grooves and the pyrolysis material.

At least in one embodiment of the disclosure, the pyrolysis material is selected from the group consisting of the epoxy, acrylic resin and silicone.

According to the at least one of aforementioned embodiments, the grooves are formed inside the circuit substrate, and each of the grooves extends to two ends of the circuit substrate in the along axis direction. When the bending part of the circuit board is under the bending state due to the external force, the grooves within the circuit substrate twist and deform in the bending direction, so as to release the bending stress on the bending part. Therefore, the bending strength of the circuit board increases.

### BRIEF DESCRIPTION OF THE DRAWINGS

To illustrate more clearly the aforementioned and the other features, merits, and embodiments of the present disclosure, the description of the accompanying figures are as follows:

FIG. 1 illustrates a cross-sectional view of a circuit board in accordance with at least one embodiment of the present disclosure.

FIG. 2 illustrates a locally stereoscopic view of a circuit board in accordance with at least one embodiment of the present disclosure.

FIG. 3 illustrates a cross-section view of a circuit board under the bending state in accordance with at least one embodiment of the present disclosure.

FIG. 4A to FIG. 4H illustrate cross-sectional views of intermediate processes for fabricating a circuit board in accordance with at least one embodiment of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In the following description, the dimensions (such as lengths, widths and thicknesses) of components (such as layers, films, substrates and regions) in the drawings are enlarged not-to-scale, and the number of components may be reduced in order to clarify the technical features of the disclosure. Therefore, the following illustrations and explanations are not limited to the number of components, the number of components, the dimensions and the shapes of components, and the deviation of size and shape caused by the practical procedures or tolerances are included. For example, a flat surface shown in drawings may have rough and/or non-linear features, while angles shown in drawings may be circular. As a result, the drawings of components shown in the disclosure are mainly for illustration and not intended to accurately depict the real shapes of the components, nor are intended to limit the scope of the claimed content of the disclosure.

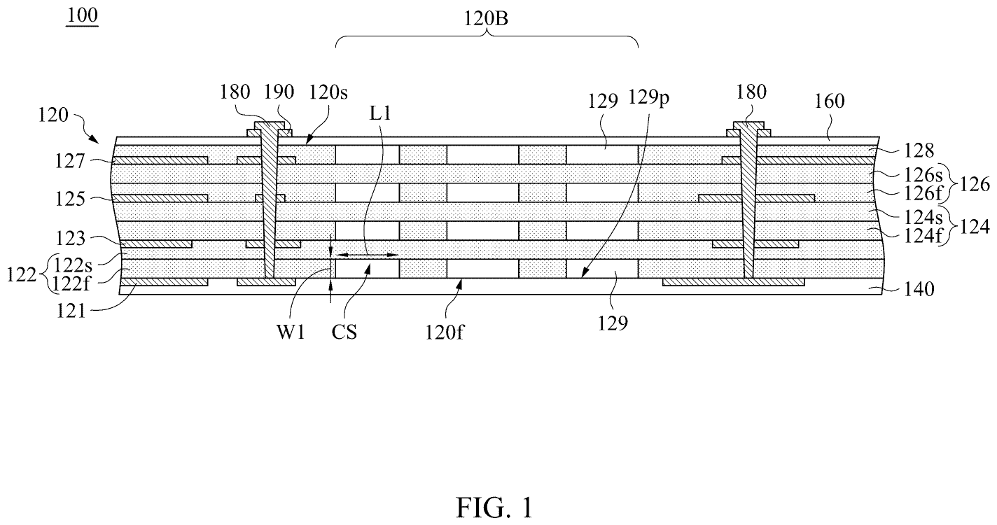

At least one embodiment of the disclosure provides a circuit board 100. Referring to FIG. 1, the circuit board 100 includes a circuit substrate 120 and a flexible insulation film 140. The circuit substrate 120 has a bending part 120B, while the circuit substrate 120 includes an insulation layer 122, a circuit layer 121 and a circuit layer 123. The circuit layer 121 and the circuit layer 123 are disposed on the insulation layer 122, and the insulation layer 122 is located between the circuit layer 121 and the circuit layer 123.

In the embodiment, the insulation layer 122 has a first layer 122f and a second layer 122s, and the first layer 122f of the insulation layer 122 is located between the flexible insulation film 140 and the second layer 122s of the insulation layer 122. Specifically, the circuit layer 121 is located at the first layer 122f of the insulation layer 122, while the circuit layer 123 is located at the second layer 122s of the insulation layer 122.

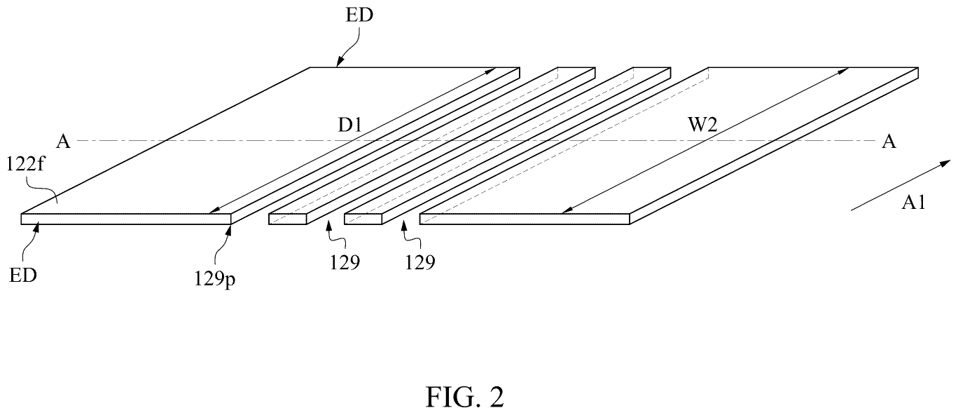

In addition, the circuit substrate 120 includes a plurality of grooves 129 which are distributed in the bending part 120B of the circuit substrate 120. FIG. 2 illustrates one of the insulation layers having the grooves 129 (e.g., the first layer 122f of the insulation layer 122). Referring to FIG. 1 and FIG. 2, each groove 129 extends to two opposite ends ED of the circuit substrate 120 in a long axis direction A1. The opening 129p of one of the grooves 129 is exposed on a first surface 120f of the circuit substrate 120.

On the other hand, the flexible insulation film 140 is disposed on the first surface 120f of the circuit substrate 120, and the flexible insulation film 140 covers the opening 129p of the groove 129. It is worth mentioning, the groove 129 is not filled with the flexible insulation film 140. In the embodiment, the grooves 129 are distributed in the first layer 122f of the insulation layer 122, but the disclosure is not limited to the embodiment. In other embodiments, the grooves 129 may be distributed in the second layer 122s of the insulation layer 122. Furthermore, the grooves 129 may be distributed in other regions of the circuit substrate 120.

For example, the circuit substrate 120 of this embodiment further includes an insulation layer 124, an insulation layer 126, an insulation layer 128, a circuit layer 125 and a circuit layer 127. The insulation layer 124 is located between the circuit layer 123 and the circuit layer 125, while the insulation layer 124 has a first layer 124f and a second layer 124s. The insulation layer 126 is located between the circuit layer 125 and the circuit layer 127, while the insulation layer 126 has a first layer 126f and a second layer 126s.

Furthermore, the insulation layer 128 is disposed on the circuit layer 127, while the circuit layer 127 is located between the insulation layer 128 and the insulation layer 126 (i.e., the second layer 126s of the insulation layer 126). Some of the grooves 129 are distributed in the first layer 124f of the insulation layer 124, while some other grooves 129 are distributed in the first layer 126f of the insulation layer 126, and the other grooves 129 are distributed in the insulation layer 128. In addition, in some embodiments, the grooves 129 may be distributed in the second layer of each insulation layer (e.g., the second layer 124f of the insulation layer 124).

The circuit board 100 further includes a protective layer 160, and this protective layer 160 is disposed on a second surface 120s of the circuit substrate 120. The first surface 120f and the second surface 120s of the circuit substrate 120 are located at two opposite sides of the circuit substrate 120 separately. The circuit layer 123 is located between the insulation layer 122 and the protective layer 160, while the protective layer 160 covers the circuit layer 121, the circuit layer 123, the circuit layer 125 and the circuit layer 127. It is worth mentioning, the opening 129p of another groove 129 is exposed on the second surface 120s of the circuit substrate 120, and the protective layer 160 covers the opening 129p of this groove 129.

The circuit board 100 further includes a plurality of conductive vias 180. These conductive vias 180 extend from one of the circuit layers to another one of the circuit layers and electrically connect these circuit layers. Specifically, the conductive vias 180 may extend from the circuit layer 121 to the circuit layer 127 and pass through the circuit layer 123 and the circuit layer 125. As a result, the circuit layer 121, the circuit layer 123, the circuit layer 125 and the circuit layer 127 are electrically connected to each other.

In various embodiments of the disclosure, the circuit substrate 120 is a rigid printed circuit board (RPCB). In other words, the insulation layers (e.g., the insulation layer 122, the insulation layer 124, the insulation layer 126 and the insulation layer 128) of the circuit substrate 120 may include insulation build-up resins, such as Ajinomoto build-up film (ABF), and the Young's modulus of the insulation layers in the circuit substrate 120 may be between 50 GPa and 80 GPa.

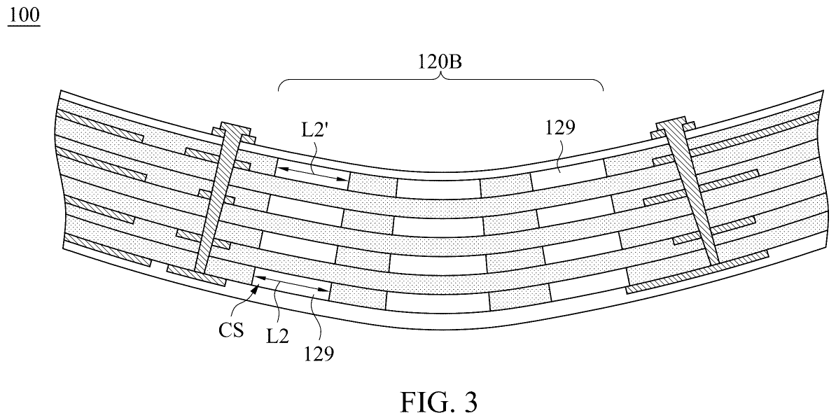

Referring to FIG. 1, FIG. 2 and FIG. 3, when the circuit board 100 is under a flatten state, the cross section CS of the groove 129 along with the line A-A is rectangular. The length L1 of this cross section CS may be between 100 μm and 500 μm, while the width W1 of the cross section CS may be between 10 μm and 50 μm. Moreover, the depth D1 of the groove 129 may be equal to the width W2 of the circuit substrate 120. That is, two opposite ends ED of the circuit substrate 120 may be connected to each other through the groove 129.

When the circuit board 100 is under a bending state, the bending part 120B of the circuit substrate 120 is bent around the long axis direction A1 (denoted in FIG. 2) which is as a bending axis. Thus, the cross section CS of at least one groove 129 is deformed. Specifically, the cross section CS of the groove 129 may be a bending trapezoid, and the length L2 of the cross section CS near the convex surface (e.g., the bottom surface of the bending part 120B in FIG. 3) is longer than the length L2′ of the cross section CS near the concave surface (e.g., the top surface of the bending part 120B in FIG. 3).

In the embodiment, the material of the flexible insulation film 140 may include polyimide (PI) or other similar insulation materials. The protective layer 160 may be a solder mask. Furthermore, the circuit board 100 may further include a plurality of soldering pads 190 which are exposed on the surface of the protective layer 160.

It is worth mentioning, the quantities of the insulation layers and the circuit layers in the circuit substrate 120 are not limited to this embodiment. In other embodiments, the quantity of the insulation layers may be one or more than one (e.g., two insulation layers), while the quantity of the circuit layers may be two or more than two (e.g., three circuit layers). Moreover, the quantity, the spacing and the distribution of the grooves 129 in the circuit substrate 120 are variable and dependent on the demanded angle for bending the bending part 120B of the circuit board 100. For example, when the required angle for bending the bending part 120B is smaller, the angle may be achieved by reducing the quantity of the grooves 129 or by increasing the spacing between the grooves 129.

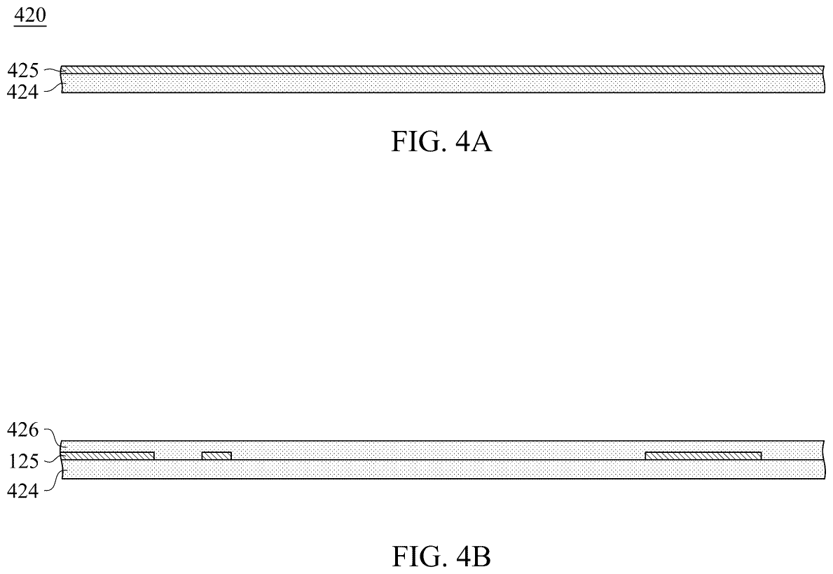

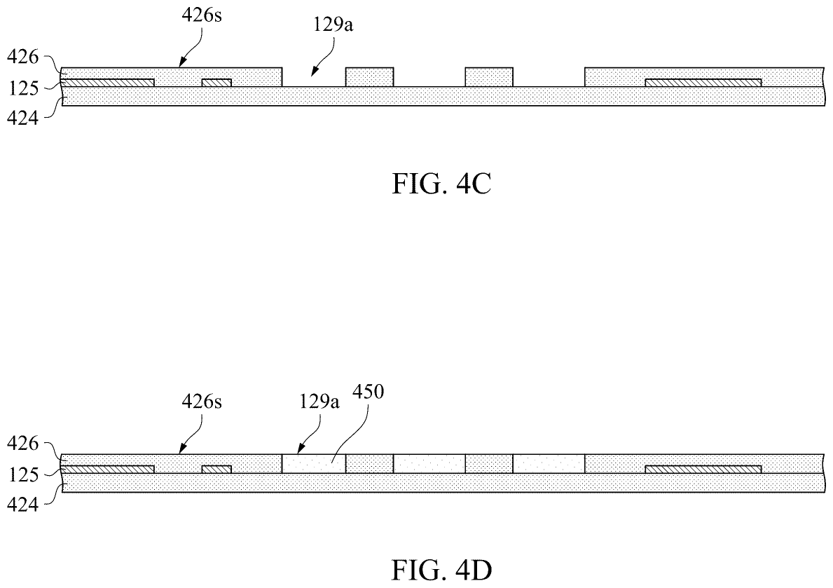

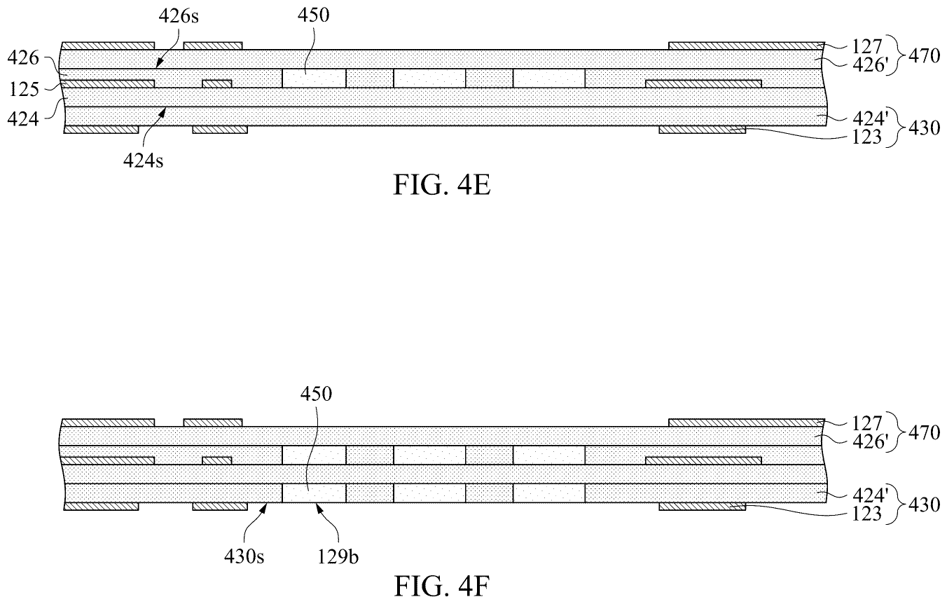

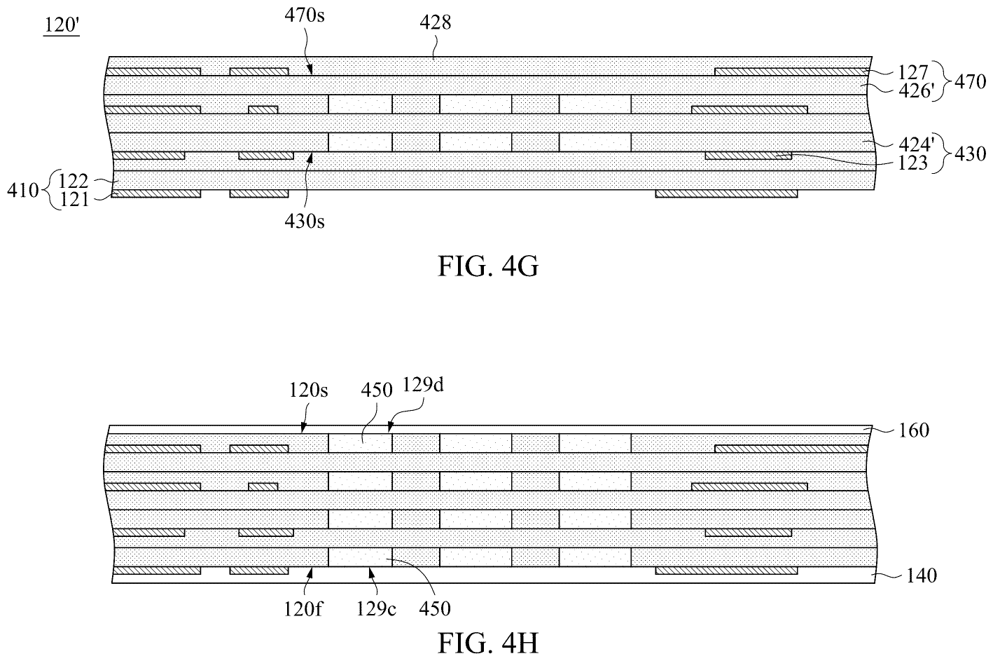

The method for fabrication of a circuit board is provided, and the aforementioned circuit board 100 is taken as an example. The fabrication includes sequent steps illustrated in FIG. 4A to FIG. 4H. Firstly, the circuit substrate 120′ (denoted in FIG. 4G) is provided, and the detailed steps of providing the circuit substrate 120′ are described as follows. Referring to FIG. 4A, firstly, the initial circuit substrate 420 which may be a copper clad laminate (CCL) is provided. The initial circuit substrate 420 includes the insulation layer 424 and the metal layer 425 which is disposed on one side of the insulation layer 424. The insulation layer 424 may be made of resin, while the materials of the metal layer 425 may include copper.

Referring to FIG. 4B, the metal layer 425 is patterned by lithography and etching, so as to form the circuit layer 125 of FIG. 1. Next, an insulation substrate 426 is disposed on the circuit layer 125 by thermal lamination. The insulation substrate 426 covers the insulation layer 424 and the circuit layer 125, while the circuit layer 125 is located between the insulation substrate 426 and the insulation layer 424. Referring to FIG. 4C, a part of the insulation substrate 426 is removed to form a plurality of grooves 129a on a surface 426s of the insulation substrate 426. Each of the grooves 129a extends to two opposite ends of the insulation substrate 426 in the long axis direction A1 (denoted in FIG. 2).

Next, as shown in FIG. 4D, a pyrolysis material 450 is disposed inside the grooves 129a, while the grooves 129a is filled with the pyrolysis material 450. It is worth mentioning, the pyrolysis temperature of the pyrolysis material 450 is between 150° C. and 200° C. For example, the pyrolysis material 450 may include materials such as epoxy, acrylic resin or silicone.

Referring to FIG. 4E, a composite substrate 470 and a composite substrate 430 are respectively disposed on the surface 426s of the insulation substrate 426 and a flat 424s of the insulation layer 424 by thermal lamination after the pyrolysis material 450 is disposed inside the grooves 129a. Specifically, the composite substrate 470 is disposed on the surface 426s of the insulation substrate 426, while the composite substrate 430 is disposed on the flat 424s of the insulation layer 424. The surface 426s of the insulation substrate 426 and the flat 424s of the insulation layer 424 both back on to the circuit layer 125, while the composite substrate 470 covers the grooves 129a and the pyrolysis material 450 inside the grooves 129a.

The composite substrate 430 includes an insulation layer 424′ and the circuit layer 123, while the composite substrate 470 includes an insulation layer 426′ and the circuit layer 127. The method for disposing the composite substrate 470 (and the composite substrate 430) includes adhering a CCL to the surface 426s of the insulation substrate 426 (and the flat 424s of the insulation layer 424) firstly. Next, the metal layer of the CCL is patterned by lithography and etching, so as to form the circuit layer 127 (and the circuit layer 123). Thus, in some embodiments, the circuit substrate is completed approximately.

However, in the embodiment illustrated by FIG. 4A to FIG. 4H, the steps for fabrication of the circuit substrate 120′ further includes removing a part of the composite substrate 430 as shown in FIG. 4F, so as to form a plurality of grooves 129b on a surface 430s of the composite substrate 430. Each of the grooves 129b extends to two opposite ends of the composite substrate 430 in the long axis direction A1 (denoted in FIG. 2). Next, the pyrolysis material 450 is disposed inside these grooves 129b.

Referring to FIG. 4G, after the pyrolysis material 450 is disposed inside the grooves 129b, an insulation layer 428 is disposed on a surface 470s of the composite substrate 470, and a composite substrate 410 is disposed on the surface 430s of the composite substrate 430 by thermal lamination. The composite substrate 410 covers the grooves 129b and the pyrolysis material 450 inside the grooves 129b, while the composite substrate 410 includes the insulation layer 122 and the circuit layer 121 located at the insulation layer 122 as shown in FIG. 1. Thus, the circuit substrate 120′ of this embodiment is completed approximately.

Referring to FIG. 4H, a part of the circuit substrate 120′ is removed after the circuit substrate 120′ is formed, so as to form a plurality of grooves 129c on the first surface 120f of the circuit substrate 120′. Each of the grooves 129c extends to two opposite ends ED (Referring to FIG. 2) of the circuit substrate 120′ in the long axis direction A1. Next, the pyrolysis material 450 is disposed inside the grooves 129c. The flexible insulation film 140 is disposed on the first surface 120f of the circuit substrate 120′ after the pyrolysis material 450 is disposed, and the flexible insulation film 140 covers the grooves 129c and the pyrolysis material 450.

In addition, the method for fabrication of a circuit board further includes removing another part of the circuit substrate 120′, so as to form a plurality of grooves 129d on the second surface 120s of the circuit substrate 120′. The first surface 120f and the second surface 120s are located on two opposite sides of the circuit substrate 120′ separately. Each of the grooves 129d extends to two opposite ends of the circuit substrate 120′ in the long axis direction A1. Next, the pyrolysis material 450 is disposed inside the grooves 129d.

The protective layer 160 is disposed on the second surface 120s of the circuit substrate 120′ after the pyrolysis material 450 is disposed inside the grooves 129d. The protective layer 160 covers the grooves 129d and the pyrolysis material 450. After the flexible insulation film 140 and the protective layer 160 are disposed on the circuit substrate 120′, the pyrolysis material 450 is heated up to its pyrolysis temperature, so as to remove the pyrolysis material 450. As a result, the cavities may be formed inside the grooves 129a, the grooves 129b, the grooves 129c and the grooves 129d.

It is worth mentioning, the method for fabrication of a circuit board further includes forming the plurality of conductive vias 180 (shown in FIG. 1), and these conductive vias 180 may be formed by drilling and electroplating during the process of forming the circuit substrate 120′. Thus, the circuit board 100 of this embodiment is completed approximately.

In conclusion, the grooves are formed inside the circuit substrate, and each of the grooves extends to two ends of the circuit substrate in the along axis direction. Therefore, when the bending part of the circuit board is under the bending state due to the external force, the grooves in the circuit substrate twist and deform in the bending direction, so as to release the bending stress on the bending part. Thus, the bending strength of the circuit board increases. Furthermore, since the Young's modulus of the insulation layer in the circuit substrate is between 50 GPa and 80 GPa, the bending strength of the circuit board of at least one embodiment of the disclosure increase while the hardness of the circuit board is maintained.

Although the embodiments of the present disclosure have been disclosed as above in the embodiments, they are not intended to limit the embodiments of the present disclosure. Any person having ordinary skill in the art can make various changes and modifications without departing from the spirit and the scope of the embodiments of the present disclosure. Therefore, the protection scope of the embodiments of the present disclosure should be determined according to the scope of the appended claims.

What is claimed is:

1. A circuit board, comprising:
a circuit substrate having a bending part and comprising:
a plurality of grooves distributed in the bending part, wherein each of the grooves extends to two opposite ends of the circuit substrate in a long axis direction, and a first opening of one of the grooves is exposed on a first surface of the circuit substrate, wherein the circuit substrate is a rigid board; and
a flexible insulation film disposed on the first surface of the circuit substrate, wherein the flexible insulation film covers the first openings of the grooves, and the grooves are not filled with the flexible insulation film.

2. The circuit board of claim 1, wherein the circuit substrate further comprises:
an insulation layer having a first layer and a second layer, wherein the first layer of the insulation layer is located between the flexible insulation film and the second layer of the insulation layer, and the grooves are distributed in the first layer of the insulation layer; and
two circuit layers disposed on the insulation layer, and the insulation layer is located between the circuit layers, one of the circuit layers is located at the first layer of the insulation layer, and the other one of the circuit layers is located at the second layer of the insulation layer.

3. The circuit board of claim 2, further comprising:
a protective layer disposed on a second surface of the circuit substrate, wherein the first surface and the second surface are located at two opposite sides of the circuit substrate separately, one of the circuit layers is located between the insulation layer and the protective layer, and the protective layer covers the one of the circuit layers.

4. The circuit board of claim 3, wherein a second opening of another one of the grooves is exposed on the second surface of the circuit substrate, and the protective layer covers the second opening of the another one of the grooves.

5. The circuit board of claim 1, wherein the circuit substrate further comprises:
an insulation layer having a first layer and a second layer, wherein the first layer of the insulation layer is located between the flexible insulation film and the second layer of the insulation layer, and the grooves are distributed in the second layer of the insulation layer; and
two circuit layers disposed on the insulation layer, and the insulation layer is located between the circuit layers, one of the circuit layers is located at the first layer of the insulation layer, and the other one of the circuit layers is located at the second layer of the insulation layer.

6. The circuit board of claim 2, wherein a Young's modulus of the insulation layer is between 50 GPa and 80 GPa.

7. The circuit board of claim 2, further comprising:
a plurality of conductive vias extending from one of the circuit layers to the other one of the circuit layers and electrically connecting the circuit layers.

8. The circuit board of claim 2, wherein the insulation layer of the circuit substrate is an Ajinomoto build-up film.

9. The circuit board of claim 1, wherein when the circuit board is under a bending state, the bending part of the circuit substrate is bent around the long axis direction that is as a bending axis, and a cross section of at least one of the grooves is deformed.

10. The circuit board of claim 9, wherein when the circuit board is under a flatten state, the cross section of the at least one of the grooves is rectangular.

11. The circuit board of claim 10, wherein when the circuit board is under the bending state, the cross section of the at least one of the grooves is a bending trapezoid.

12. A method for fabricating a circuit board, comprising:
providing a circuit substrate;
removing a part of the circuit substrate to form a plurality of first grooves on a first surface of the circuit substrate, wherein each of the first grooves extends to two opposite ends of the circuit substrate in a long axis direction;
disposing a pyrolysis material inside the first grooves, wherein a pyrolysis temperature of the pyrolysis material is between 150° C. and 200° C.;
disposing a flexible insulation film on the first surface of the circuit substrate after the pyrolysis material is disposed, wherein the flexible insulation film covers the first grooves and the pyrolysis material; and
heating up the circuit substrate to the pyrolysis temperature of the pyrolysis material after the flexible insulation film is disposed on the circuit substrate, so as to remove the pyrolysis material.

13. The method of claim 12, wherein providing the circuit substrate comprises:
providing an initial circuit substrate comprising:
an insulation layer; and
a metal layer disposed on one side of the insulation layer;
patterning the metal layer to form a circuit layer;
disposing an insulation substrate on the circuit layer, wherein the insulation substrate covers the insulation layer and the circuit layer, and the circuit layer is located between the insulation layer and the insulation substrate;
removing a part of the insulation substrate to form a plurality of second grooves on a second surface of the insulation substrate, wherein each of the second grooves extends to two opposite ends of the insulation substrate in the long axis direction;
disposing the pyrolysis material inside the second grooves; and
disposing at least one composite substrate respectively on the second surface of the insulation substrate and a flat of the insulation layer after the pyrolysis material is disposed inside the second grooves, wherein the second surface of the insulation substrate and the flat of the insulation layer back on to the circuit layer, and one of the at least one composite substrate covers the second grooves and the pyrolysis material inside the second grooves.

14. The method of claim 13, further comprising:
removing another part of the circuit substrate to form a plurality of third grooves on a third surface of the circuit substrate, and the third surface and the first surface are separately located at two opposite sides of the circuit substrate, wherein each of the third grooves extends to two opposite ends of the circuit substrate in the along axis direction;
disposing the pyrolysis material inside the third grooves; and
disposing a protective layer on the third surface of the circuit substrate after the pyrolysis material is disposed inside the third grooves, wherein the protective layer covers the third grooves and the pyrolysis material.

15. The method of claim 12, wherein the pyrolysis material is selected from the group consisting of the epoxy, acrylic resin and silicone.
